(19) United States
(12) Patent Application Publication
(10) Pub. No.: US 2026/0165168 A1
(43) Pub. Date: Jun. 11, 2026

(54) METHOD FOR MANUFACTURING CORE SUBSTRATE AND CORE SUBSTRATE INCLUDED IN A PACKAGING SUBSTRATE

(71) Applicant: Absolics Inc., Covington, GA (US)

(72) Inventor: DONGJUN SHIN, Covington, GA (US)

(73) Assignee: Absolics Inc., Covington, GA (US)

(21) Appl. No.: 19/411,332

(22) Filed: Dec. 7, 2025

Related U.S. Application Data
(60) Provisional application No. 63/729,450, filed on Dec. 8, 2024.

(51) Int. Cl. H10W 70/68; B32B 3/26; B32B 7/12; B32B 17/10; H10W 70/05; H10W 70/692

(52) U.S. Cl. CPC H10W 70/682; B32B 3/266; B32B 7/12; B32B 17/10; H10W 70/095; H10W 70/692; B32B 2307/202; B32B 2307/206; B32B 2307/7376

(57) ABSTRACT

A method for manufacturing a core substrate included in a packaging substrate, comprises: operation A, preparing a glass core in which through-holes and a cavity are disposed; operation B, preparing an adhesive laminate in which an adhesive layer is disposed on a lower surface of the glass core; operation C, disposing a cavity element in the cavity of the adhesive laminate; operation D, preparing a fill-in laminate by disposing a dispensing material in a space between the cavity element and a wall surface of the cavity; operation E, preparing an adhesion-strengthening treatment layer by performing an adhesion-strengthening treatment on a surface of the fill-in laminate; operation F, preparing an insulating laminate by forming a first surface insulating layer on an upper surface of the glass core of the fill-in laminate; and operation G, preparing the core substrate by removing the adhesive layer and forming a second surface insulating layer.

### CROSS-REFERENCE TO RELATED APPLICATION

This application claims priority of U.S. Provisional Ser. No. 63/729,450 , filed on Dec. 8, 2024, the entire disclosure of which is hereby incorporated by reference for all purposes.

### BACKGROUND

### Technical Field

Embodiments relate to a method for manufacturing a core substrate and a core substrate included in a packaging substrate.

### Description of Related Art

In manufacturing electronic components, forming circuits on a semiconductor wafer is referred to as a front-end process (FE: Front-End), and assembling the wafer into a state usable in an actual product is referred to as a back-end process (BE: Back-End). A packaging process is included in the back-end process.

Among the four core technologies of the semiconductor industry that have enabled the rapid advance of electronic products are semiconductor technology, semiconductor packaging technology, manufacturing-process technology, and software technology. Semiconductor technology has evolved in various forms—such as sub-micrometer to nanometer line widths, more than ten million cells, high-speed operation, and significant heat generation—whereas, comparatively, the technology for perfectly packaging the same has not kept pace. Accordingly, the electrical performance of a semiconductor may be determined by the packaging technology and the resulting electrical interconnection, rather than by the performance of the semiconductor technology itself.

While ceramics or resins are applied as materials for packaging substrates, research is underway to apply silicon or glass as high-end packaging substrates; in particular, packaging substrates having a cavity structure have been developed by applying a glass core.

Related art includes Korean Laid-Open Patent No. 10-2015-0022560 and Korean Registered Patent No. 10-1253514.

### SUMMARY

In some embodiments, a method for manufacturing a core substrate with excellent adhesion using a simplified process, a core substrate, and a packaging substrate applying the same is provided.

According to the embodiments, an embodiment presents a method for manufacturing a core substrate included in a packaging substrate.

The method for manufacturing the core substrate comprises: operation A of preparing a glass core in which through-holes and a cavity are disposed; operation B of preparing an adhesive laminate in which an adhesive layer is disposed on a lower surface of the glass core such that the glass core and the adhesive layer are vertically arranged; operation C of disposing a cavity element within the cavity of the adhesive laminate; operation D of preparing a fill-in laminate by disposing a dispensing material in a space between the cavity element and a wall surface of the cavity; operation E of preparing an adhesion-strengthening treatment layer by performing an adhesion-strengthening treatment on a surface of the fill-in laminate; operation F of preparing an insulating laminate by forming a first surface insulating layer on an upper surface of the glass core of the fill-in laminate; and operation G of preparing the core substrate by removing the adhesive layer from the insulating laminate and forming a second surface insulating layer on a lower surface of the glass core.

An electrically conductive layer as a core electrically conductive layer may be disposed on at least a portion of a surface of the glass core.

A process including an adhesion-strengthening treatment is substantially not applied between operation A and operation B.

In operation B, the adhesive layer may be constituted by an adhesive material disposed on a support film.

A thickness of the adhesive material may be 10 μm or greater.

In operation E, the adhesion-strengthening treatment may include processing a surface such that a surface roughness (Ry) of the surface of the core electrically conductive layer is within a range of 20 nm to 200 nm.

In operation E, the adhesion-strengthening treatment may include performing a bonding-strength enhancing compound treatment on a surface of the glass core.

After operation F, a wiring operation of forming electrical conductivity may further be disposed.

In the wiring operation, an electrically conductive layer on the first surface insulating layer may have an adhesion strength of 350 gf/cm or more on the glass core.

In operation G, substantially no residue of the adhesive layer remains on the core electrically conductive layer on the lower surface of the glass core from which the adhesive layer has been removed.

The operation G may further include, after removal of the adhesive layer, adding an adhesion-strengthening treatment layer to the insulating laminate by performing an adhesion-strengthening treatment; and, after addition of the adhesion-strengthening treatment layer, forming the second surface insulating layer on the lower surface of the glass core. In this case, for the core electrically conductive layer disposed in the through-hole, a thickness of the adhesion-strengthening treatment layer on any one of the first surface insulating layer side and the second surface insulating layer side may be formed thicker.

The operation G may proceed, without adding an adhesion-strengthening treatment layer to the insulating laminate after removal of the adhesive layer by performing an adhesion-strengthening treatment, to forming the second surface insulating layer on the lower surface of the glass core. In this case, for the core electrically conductive layer disposed in the through-hole, the adhesion-strengthening treatment layer may be disposed only on any one of the first surface insulating layer side and the second surface insulating layer side.

The manufacturing method may further include a wiring operation of forming electrical conductivity on the first surface insulating layer and/or under the second surface insulating layer after the operation G.

In the wiring operation, an electrically conductive layer on the first surface insulating layer may have an adhesion strength of 350 gf/cm or more on the glass core.

In the wiring operation, an electrically conductive layer under the second surface insulating layer may have an adhesion strength of 350 gf/cm or more on the glass core.

A core substrate according to another embodiment is a core substrate applied to a packaging substrate, and includes: a glass core in which through-holes and a cavity are disposed; a cavity element that is an element disposed in the cavity; a first surface insulating layer that is an insulating layer disposed on an upper surface of the glass core; and a second surface insulating layer that is an insulating layer disposed on a lower surface of the glass core.

An electrically conductive layer as a core electrically conductive layer is disposed on at least a portion of a surface of the glass core; a dispensing material is disposed in a space between the cavity element and the wall surface of the cavity; and an electrically conductive layer is further disposed on the second surface insulating layer.

The electrically conductive layer on the second surface insulating layer may have an adhesion strength of 350 gf/cm or more on the glass core.

Substantially no residue of the adhesive layer remains on the core electrically conductive layer on the side where the adhesion-strengthening treatment layer is not disposed.

For the core electrically conductive layer disposed in the through-hole, a thickness of the adhesion-strengthening treatment layer on any one of the first surface insulating layer side and the second surface insulating layer side may be thicker.

For the core electrically conductive layer disposed in the through-hole, the adhesion-strengthening treatment layer may be disposed only on any one of the first surface insulating layer side and the second surface insulating layer side.

### BRIEF DESCRIPTION OF THE DRAWINGS

FIGS. 1 to 3 are conceptual cross-sectional views explaining a conventional process for manufacturing a core substrate.

FIGS. 4 to 6 are conceptual cross-sectional views explaining a process for manufacturing a core substrate according to an embodiment.

FIGS. 7 and 8 are conceptual cross-sectional views respectively explaining a packaging substrate to which a core substrate according to an embodiment is applied.

### DESCRIPTION OF THE EMBODIMENTS

Hereinafter, embodiments will be described in detail with reference to the accompanying drawings so that those skilled in the art can readily practice the invention. However, the embodiments may be implemented in various different forms and are not limited to the embodiments set forth herein. Like reference numerals designate like elements throughout this specification.

Throughout this specification, the term “combinations thereof” included in a Markush-type expression means one or more mixtures or combinations selected from the group consisting of the components recited in the Markush-type expression, and means that one or more selected from the group consisting of the components is/are comprised.

In this specification, terms such as “first,” “second,” or “A,” “B” are used to distinguish identical terms from each other. In addition, unless the context clearly indicates otherwise, singular expressions include plural expressions.

In this specification, a “˜group” may mean that a compound corresponding to “˜” or a derivative of “˜” is comprised in the compound.

In this specification, the statement that B is positioned over A means that B is positioned directly in contact over A or positioned over A with another layer interposed therebetween, and is not to be construed as being limited to B being positioned in contact with the surface of A.

In this specification, the statement that B is connected to A means that A and B are directly connected or connected through another component interposed between A and B, and, unless otherwise specified, is not to be construed as being limited to A and B being directly connected.

In this specification, unless otherwise described, singular expressions are to be construed, in light of the context, as including singular or plural.

In manufacturing a core substrate that applies plate-shaped glass as a support, it is necessary to maintain interlayer bonding force—particularly adhesion between a metallic electrically conductive layer and another layer—at or above a certain level in order to suppress interlayer delamination. To this end, it is often the case that an adhesion-strengthening treatment is performed during the manufacturing process; however, this can bring other drawbacks.

In manufacturing a core substrate that applies a cavity, an adhesive layer is applied to fix the positions of the cavity and an element inserted into the cavity (cavity element). After the adhesive layer serves to fix these positions, once their positions are fixed by other constituents, the adhesive layer is removed and is generally not comprised in the completed core substrate.

However, during removal of the adhesive layer, adhesive residues may remain in the core substrate, which can become another cause of defect occurrence; accordingly, it is necessary to reduce this.

The inventors identified these problems in the course of manufacturing the core substrate and present the embodiments below.

### Method for Manufacturing Core Substrate

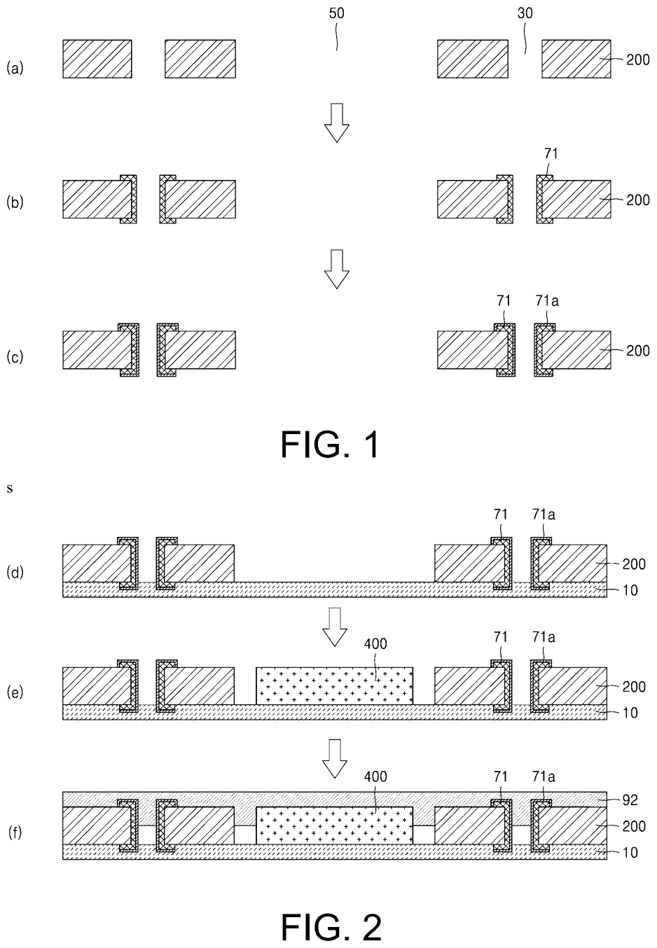

FIGS. 1 to 3 are conceptual cross-sectional views explaining a conventional process for manufacturing a core substrate, and FIGS. 4 to 6 are conceptual cross-sectional views explaining a process for manufacturing a core substrate according to an embodiment. With reference to FIGS. 1 to 6, the embodiments will be described in greater detail below. In each drawing, the labels “(a), (b), . . . ” are provided for convenience of description and do not indicate a process operation or sequence.

To achieve the above objective, a method for manufacturing a core substrate 4000 according to an embodiment is a method for manufacturing the core substrate 4000 included in a packaging substrate, and comprises: operation A; operation B; operation C; operation D; operation E; operation F; and operation G.

Operation A is preparing a glass core 200 in which a through-hole 30 or a cavity 50 is disposed (see (a) of FIG. 4).

It is preferable that the glass core 200 applies plate-shaped glass used for semiconductors; for example, borosilicate plate-shaped glass or alkali-free plate-shaped glass may be applied, but the invention is not limited thereto. By way of example, products of SCHOTT, AGC, or Corning may be applied, but the invention is not limited thereto.

A thickness of the glass core 200 may be 100 μm or more, 200 μm or more, 250 μm or more, 300 μm or more, 350 μm or more, or 400 μm or more. The thickness may be 3000 μm or less, 2500 μm or less, 2000 μm or less, 1500 μm or less, or 1000 μm or less. In such cases, it is advantageous in that the glass core has mechanical strength suitable for application to a packaging substrate.

A through-hole 30 and/or a cavity 50 may be disposed in the glass core 200. These may be manufactured by forming defects at predetermined positions in the plate-shaped glass by a laser or the like and then etching, or may be formed by laser etching.

The cavity 50 may be a cavity of a form that penetrates the glass core 200 (a full cavity).

An electrically conductive layer disposed in the glass core 200 is referred to as a core electrically conductive layer 71.

As the electrically conductive layer, an electrically conductive metal layer such as copper or a copper alloy may be applied.

The electrically conductive layer may be formed by electroplating or the like and may be disposed on a surface of the glass core 200. Here, the “surface” means all surfaces exposed to the outside, including the inside of the through-hole and an inner wall of the cavity. As needed, a sputter layer or a primer layer may be disposed between the core electrically conductive layer 71 and the glass core 200. The sputter layer may be, by way of example, a sputter layer of any one selected from the group consisting of titanium, chromium, nickel, copper, and combinations thereof. The primer layer may be a polymer resin layer in which a copper seed or the like is embedded, but the invention is not limited thereto.

The core electrically conductive layer 71 may be disposed in the through-hole 30 (see (b) of FIG. 4).

An inner surface of the cavity 50 may be exposed as a glass surface or as a surface of a metal layer (not shown).

A thickness of the core electrically conductive layer 71 may be 10 μm or more. The thickness may be 10 μm or more, 15 μm or more, or 20 μm or more. The thickness may be 100 μm or less, 90 μm or less, 80 μm or less, 70 μm or less, 60 μm or less, or 50 μm or less.

A width of the core electrically conductive layer 71 may be 10μm or more. The width may be 10 μm or more, 15 μm or more, or 20 μm or more. The width may be 100 μm or less, 90 μm or less, 80 μm or less, 70 μm or less, 60 μm or less, or 50 μm or less.

In a case where the core electrically conductive layer 71 fills the through-hole, a radius of the core electrically conductive layer in the through-hole is treated as the thickness or the width above.

In such cases, it can assist in enabling efficient wiring layout while the packaging substrate has an overall thin thickness.

In FIG. 4, (a) and (b) are indicated sequentially for convenience of description.

A glass substrate 200 in which the core electrically conductive layer 71 is formed may be applied to operation A.

A glass substrate 200 in which the core electrically conductive layer 71 is not formed may be applied to operation A. In this case, a process of forming the core electrically conductive layer may be carried out after operation A.

Operation B is an operation of preparing an adhesive laminate 1000 in which an adhesive layer 10 is disposed on a lower surface of the glass core 200 such that the glass core 200 and the adhesive layer 10 are vertically arranged (see (c) of FIG. 4).

Adhesive layer 10 may be an adhesive film applied for the purpose of position fixing in semiconductor processes. For example, the adhesive layer 10 may be constituted by an adhesive material (not shown) disposed on a support film (not shown). The adhesive material may have a thickness of 10 μm or more, 15 μm or more, or 20 μm or more. The thickness may be 120 μm or less, 100 μm or less, 80 μm or less, or 60 μm or less. In such cases, it is advantageous for obtaining a stable fixing effect.

The adhesive layer 10 may be one whose adhesion changes by a specific treatment, such as irradiation with ultraviolet light. After achieving the purpose of position fixing, when a treatment such as irradiation with ultraviolet light of a particular wavelength is performed, an adhesive layer may be applied in which the adhesion of the adhesive material becomes relatively lower, thereby facilitating detachment.

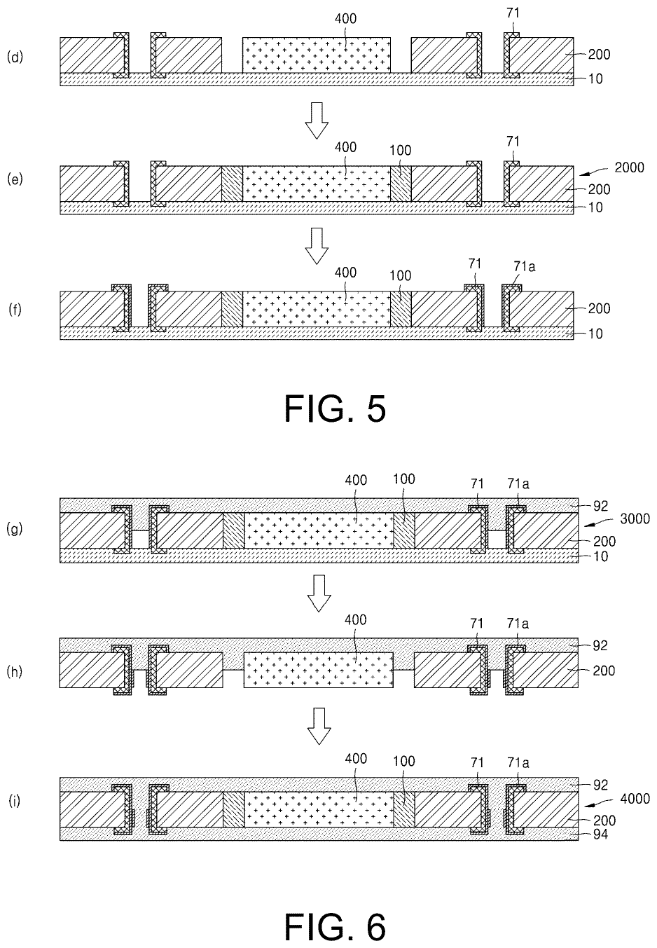

Operation C is disposing a cavity element 400 in the cavity 50 of the adhesive laminate 1000 (see (a) of FIG. 5).

The cavity element 400 is a generic term for an element disposed in the cavity.

The cavity element 400 may be one electronic element, or a plurality of electronic elements may be disposed.

The cavity element 400 may be the electronic element as is, or may be in a molded form in which the electronic element is wrapped with an insulating layer or the like.

Positions of the cavity element 400 and the cavity 50 may be fixed by the adhesive material mentioned above. Here, “fixed” means fixed to a degree that their relative positions do not change in subsequent processes.

Operation D is preparing a fill-in laminate 2000 by disposing a dispensing material 100 in a space between the cavity element 400 and a wall surface of the cavity 50 (see (b) of FIG. 5).

As the dispensing material 100, an insulating material may be applied.

The insulating material may be, for example, an epoxy resin, an epoxy resin containing a filler, or a polyester resin containing a filler, among others.

By way of example, the insulating material may comprise ABF (Ajinomoto Build-up Film), EMC (Epoxy Molding Compound), MPI (Modified Polyimide), LCP (liquid crystal polymer), CUF (capillary underfill) materials, NCF (non-conductive films), or NCP (non-conductive pastes).

The dispensing material 100 may be prepared in a film form, then disposed in the space by a method such as heating and vacuum lamination, and then cured or semi-cured.

Operation E is preparing an adhesion-strengthening treatment layer 71a by performing an adhesion-strengthening treatment on a surface of the fill-in laminate 2000 (see (c) of FIG. 5).

The “surface” refers to a surface exposed to the outside in the fill-in laminate 2000, and refers, by way of example, to an upper surface of the glass core 200, an internal surface of the core, and a surface of the core electrically conductive layer.

As the adhesion-strengthening treatment applied to the surface, a surface oxidation treatment, a surface etching treatment, a treatment with a silicon-based compound, or a treatment with an acrylic-based compound may be applied.

By applying the adhesion-strengthening treatment, adhesion between an insulating layer described below and the glass core and/or the core electrically conductive layer is enhanced.

In operation E, the adhesion-strengthening treatment may comprise processing the surface such that an arithmetic average surface roughness (Ra) of the core electrically conductive layer 71 becomes 25 nm to 150 nm. The Ra may be 25 nm or more, 30 nm or more, 35 nm or more, 40 nm or more, 45 nm or more, or 50 nm or more. The Ra may be 150 nm or less, 120 nm or less, 90 nm or less, or 70 nm or less. Within these ranges, a more stable resistance to interlayer delamination can be obtained. In addition, it may be more efficient for high-frequency power applications.

In operation E, the adhesion-strengthening treatment may comprise processing the surface such that a maximum height surface roughness (Ry) of the core electrically conductive layer 71 becomes 20 nm to 200 nm. The Ry may be 20 nm or more, 25 nm or more, 30 nm or more, 35 nm or more, 40 nm or more, 45 nm or more, or 50 nm or more. The Ry may be 200 nm or less, 180 nm or less, 150 nm or less, 120 nm or less, 90 nm or less, or 70 nm or less. Within these ranges, a more stable resistance to interlayer delamination can be. In addition, it may be more efficient for high-frequency power applications.

The Ra and Ry may be measured in accordance with ISO 4287:1997.

A surface oxidation treatment is a treatment that applies an oxidizing agent to a surface of the glass core 200 to induce the surface to be etched or to form an oxide.

A surface etching treatment is a treatment that applies an etching solution or an etching gas to a surface of the glass core 200 so that at least a portion of the surface is etched.

By the oxidation treatment or the etching treatment, a surface roughness of the surface may be controlled.

The adhesion-strengthening treatment may be a treatment of performing a bonding-strength enhancing compound treatment on a surface of the glass core 200.

As the bonding-strength enhancing compound, a silicon-based compound, an azole-based compound, or an amine-based compound may be applied, and a thin coating layer thereof may be formed on the surface.

As the silicon-based compound, a silicone-based adhesive may be applied.

The silicone adhesive may be a peroxide-curing silicone adhesive. The silicone adhesive may be an addition-reaction type silicone adhesive. The peroxide-curing silicone adhesives and addition-reaction silicone adhesives are not limited, and may be applied without restriction so long as they are those commonly applied in the field of tack or adhesion technologies. By way of example, the peroxide-curing silicone adhesive may comprise DOWSIL SH 4280 (Dow) or KR-100 (Shin-Etsu). By way of example, the addition-reaction type silicone adhesive may comprise DOWSIL 4585 (Dow) or KR-3700 (Shin-Etsu).

As the silicon-based compound, a silane coupling agent may be applied.

The silane coupling agent may comprise, at one terminal end, for example, a methoxy group and/or an ethoxy group. In addition, the silane compound may include, at the other terminal end, an amino group, a vinyl group, an epoxy group, a methacryloxy group, an acryloxy group, a ureido group, a mercapto group, a sulfido group, or an isocyanate group.

The azole-based compound may be imidazole, benzimidazole, triazole, benzotriazole, or a derivative thereof. Specifically, it may comprise benzotriazole, tolyltriazole, hydroxybenzotriazole, or benzimidazole.

As the amine-based compound, an amino carboxylic acid may be applied, by way of example.

The adhesion-strengthening treatment may be applied as a combination of etching and a bonding-strength enhancing compound treatment.

By way of example, Novabond (Atotech), Cz 8401 (Cz), Nanotus (YMT), or GliCAP (MK) may be applied.

By such treatment, adhesion between the electrically conductive layer and an insulating layer described below may be further improved.

The operation F is preparing an insulating laminate 3000 by forming a first surface insulating layer 92 on an upper surface of the glass core 200 of the fill-in laminate 2000 (see (g) of FIG. 6).

The first surface insulating layer 92 may be prepared by a method for forming an insulating layer on a packaging substrate. For example, the insulating layer may be an inorganic layer or an organic-inorganic composite layer.

As the inorganic layer, a metal-oxide sputtered layer may be applied, by way of example.

The organic-inorganic composite layer may comprise insulating particles and a binder.

As the binder, an acrylic resin, an epoxy resin, or a modified resin thereof may be applied, and a material applicable for purposes such as molding in electronic devices may be applied.

The organic-inorganic composite layer may be a mixture of an acrylic resin and a filler, a mixture of an acrylic resin and an epoxy resin with a filler, or a mixture of an epoxy resin and a filler. The filler may be an inorganic particle, and silica particles may be applied by way of example.

Commercial products such as ABF (Ajinomoto Build-up Film), EMC (Epoxy Molding Compound), MPI (Modified Polyimide), CUF (Capillary Underfill) materials, NCF (Non-Conductive Films), and NCP (Non-Conductive Pastes) may be applied.

The dispensing material may be transformed into a flowable form, fill a space between the cavity inner wall and the die block, be disposed within the packaging glass core, and then be cured. For example, the dispensing material may be fluidized by heating, placed at an appropriate position, and then thermally cured or the like so as to fix a position of the die block within the cavity inner wall.

The operation G is preparing the core substrate 4000 by removing the adhesive layer 10 from the insulating laminate 3000 and forming a second surface insulating layer 94 on a lower surface of the glass core 200. As needed, an adhesion-strengthening treatment may additionally be performed after removal of the adhesive layer and before formation of the second surface insulating layer 94. In this case, an adhesion-strengthening layer is also disposed on the lower surface (see (h) and (i) of FIG. 6). In the drawings, an adhesion-strengthening treatment layer 71a is indicated in duplicate on some surfaces on which the adhesion-strengthening treatment has been performed two or more times (see (i) of FIG. 6 and FIG. 8). However, depending on the type of adhesion-strengthening treatment, portions treated twice may not be clearly distinguishable from portions not so treated.

Removal of the adhesive layer 10 is performed in consideration of characteristics of the adhesive layer.

By way of example, a method may be applied in which, after irradiating the adhesive layer with ultraviolet light, the adhesion-weakened adhesive layer is physically removed.

A process comprising an adhesion-strengthening treatment is substantially not applied between the operation A and operation B. As will be described in detail for the conventional method below, this is one of the important differences from the conventional method.

A layer to which the adhesive layer 10 has been adhered and from which it has been detached is not subjected to the adhesion-strengthening treatment described above. In other words, in the embodiment, the adhesion-strengthening treatment is performed after the adhesive layer 10 is applied, and the adhesive layer 10 is not attached to a surface on which the adhesion-strengthening treatment has been performed.

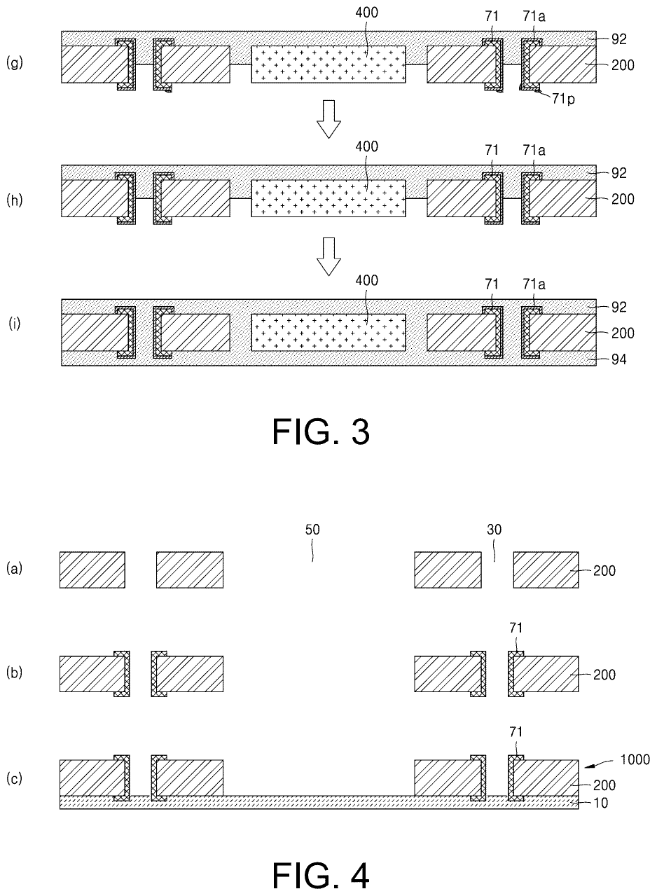

On a surface on which the adhesion-strengthening treatment has been performed, surface roughness increases and/or sites capable of forming chemical bonds on the surface are activated. If the adhesive layer 10 is applied thereto, adhesion between the adhesive material of the adhesive layer and the treated surface acts quite strongly, making detachment difficult. In addition, upon detachment, residues of the adhesive material (residue of the adhesive layer, reference numeral 71p in FIG. 3) are likely to remain. To remove these, a desmear process or the like needs to be applied, which is one cause of complicating the process. Furthermore, even after a desmear process, complete removal is not easy.

The embodiment can simplify the process while solving these problems.

In operation G, substantially no residue 71p of the adhesive layer remains on the core electrically conductive layer 71 on the lower surface of the glass core 200 from which the adhesive layer has been removed.

After removal of the adhesive layer 10, a cleaning treatment may be selectively applied as needed. That is, operation G may further comprise a cleaning process after removal of the adhesive layer 10 and before formation of the second surface insulating layer 94.

The cleaning treatment may apply plasma (e.g., O2 plasma), among others, but is not limited thereto.

A wiring operation of forming an electrically conductive layer 650 may further be disposed after operation F.

In the wiring operation, an electrically conductive layer on the first surface insulating layer 92 has an adhesion strength on the glass core of 350 gf/cm or more. The adhesion strength may be 350 gf/cm or more, 400 gf/cm or more, 450 gf/cm or more, or 500 gf/cm or more. The adhesion strength may be 1300 gf/cm or less. In such cases, excellent adhesion can be maintained over a long term even during operation of the packaging substrate.

In the wiring operation, an electrically conductive layer on the second surface insulating layer 94 has an adhesion strength on the glass core of 350 gf/cm or more. The adhesion strength may be 350 gf/cm or more, 400 gf/cm or more, 450 gf/cm or more, or 500 gf/cm or more. The adhesion strength may be 1300 gf/cm or less. In such cases, excellent adhesion can be maintained over a long term even during operation of the packaging substrate.

A conventional method contrasted with the above embodiment is described below.

A glass core 200 in which a through-hole 30 and a cavity 50 are disposed is prepared (see (a) of FIG. 1). As in the embodiment above, a core electrically conductive layer 71 may be disposed in the glass core 200 (see (b) of FIG. 1).

An adhesion-strengthening treatment is performed on a surface of the core electrically conductive layer 71 and/or the glass core 200 to prepare an adhesion-strengthening treatment layer 71a. This is to enhance adhesion of an insulating layer and the like to be applied later. At this time, the adhesion-strengthening treatment layer 71a is applied not only to the upper surface of the glass substrate 200 and the core electrically conductive layer 71 but also to the lower surface.

Thereafter, an adhesive layer 10 is applied for the purpose of fixing a position of a cavity element 400 (see (d) of FIG. 2). Typically, the adhesive layer 10 is disposed on a lower side of the glass substrate 200 and comes into direct contact with the lower surface of the glass substrate 200 and the underside of the core electrically conductive layer 71. That is, the adhesive layer 10 comes into direct contact with the adhesion-strengthening treatment layer 71a mentioned above.

A cavity element 400 is disposed in the cavity 50 of the glass core 200 on which the adhesive layer 10 is disposed (see (e) of FIG. 2). Subsequently, a first surface insulating layer 92 is disposed on the glass substrate 200 (see (f) of FIG. 2), and the adhesive layer 10 is removed (see (g) of FIG. 3).

Removal of the adhesive layer 10 may be performed by a method in which the adhesive strength is weakened by, for example, ultraviolet irradiation and then the layer is physically removed, but the invention is not limited thereto.

The adhesive layer 10 may be one in which an adhesive material is disposed on a support film, and a portion of the adhesive material may remain on the underlying glass substrate 200. Such residues of the adhesive layer (residues of the adhesive material, 71p) are materials having adhesiveness and have sufficient adhesion to fix positions of the glass substrate and the cavity element. In addition, with the adhesion-strengthening treatment described above applied thereto, the adhesion between the adhesive layer 10 and the glass substrate 200 acts very strongly. Accordingly, when removing the adhesive layer 10, the peeling stress applied to the glass substrate is considerably high. Further, the strengthened adhesion and a stepped surface of the electrically conductive layer 71 facilitate residual adhesion of the adhesive material.

The residues 71p may affect adhesion or planarity of subsequently laminated layers. Therefore, after removal of the adhesive layer 10, it is essential to remove the residues 71p remaining on the glass substrate 200 (see (h) of FIG. 3). To this end, a residue-removal treatment is required. After performing the residue-removal treatment, a second insulating layer 94 is disposed (see (i) of FIG. 3).

Such a process imparts enhanced adhesion to an adhesive layer that is scheduled to be removed, and requires additional processing for its removal, thereby making the process conditions complicated and irrational. The embodiment solves these problems.

### Core Substrate and Packaging Substrate

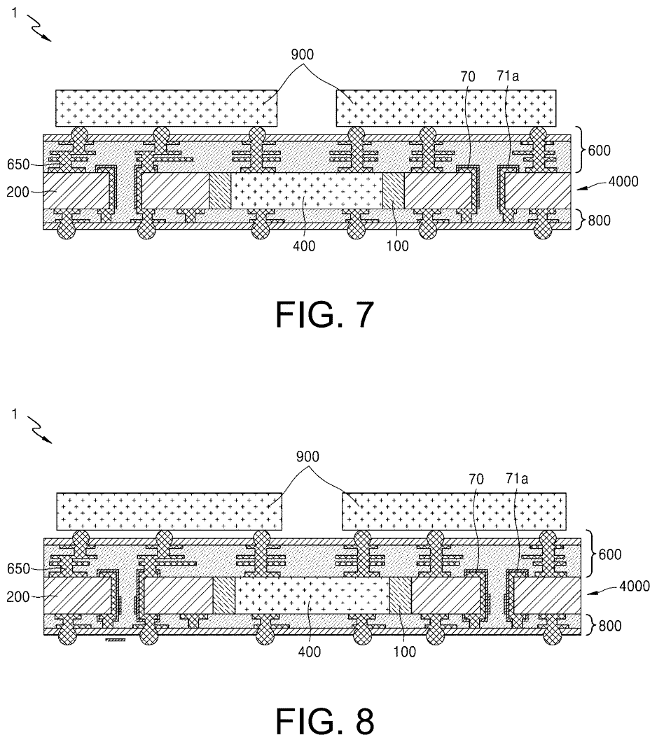

(i) of FIG. 6 is a conceptual cross-sectional view explaining the core substrate 4000, and FIGS. 7 and 8 are conceptual cross-sectional views respectively explaining a packaging substrate to which the core substrate according to an embodiment is applied. With reference to (i) of FIG. 6 and FIGS. 7 and 8, the core substrate 4000 and the packaging substrate 1 will be described in detail.

A core substrate 4000 of the embodiment is a core substrate applied to a packaging substrate 1, and comprises: a glass core 200 in which a through-hole 30 and a cavity 50 are disposed; a cavity element 400 that is an element disposed in the cavity 50; a first surface insulating layer 92 that is an insulating layer disposed on an upper surface of the glass core 200; and a second surface insulating layer 94 that is an insulating layer disposed on a lower surface of the glass core 200.

A core electrically conductive layer 71, which is an electrically conductive layer, is disposed on at least a portion of a surface of the glass core 200.

A dispensing material 100 is disposed in a space between the cavity element 400 and a wall surface of the cavity 50.

On the side of the core electrically conductive layer 71 where the adhesion-strengthening treatment layer 71a is not disposed, residues 71p of the adhesive layer do not substantially remain.

For the core electrically conductive layer 71 disposed in the through-hole 30, the adhesion-strengthening treatment layer 71a is disposed only on one of the first surface insulating layer 92 side and the second surface insulating layer 94 side (see FIG. 7).

For the core electrically conductive layer 71 disposed in the through-hole 30, a thickness of the adhesion-strengthening treatment layer 71a on one of the first surface insulating layer 92 side and the second surface insulating layer 94 side may be thicker (see FIG. 8).

In the embodiment, since the adhesion-strengthening treatment layer 71a is manufactured without being in direct contact with the layer on which the adhesive layer had been disposed during the manufacturing process, residues of the adhesive layer do not substantially remain at the position where the adhesive layer was attached, and a core substrate of excellent quality can be efficiently provided.

An electrically conductive layer 650 may be further disposed on the first surface insulating layer 92.

The electrically conductive layer on the first surface insulating layer 92 may have an adhesion strength of 350 gf/cm or more on the glass core.

On the first surface insulating layer 92, a cover layer (not shown) may be further comprised that covers the insulating layer and the electrically conductive layer with, for example, a PI film and exposes a contact portion with a bump.

The foregoing configurations on the first surface insulating layer 92 are collectively referred to as an upper layer 600.

An electrically conductive layer may further be disposed on the second surface insulating layer 94 (not shown).

The electrically conductive layer on the second surface insulating layer 94 has an adhesion strength on the glass core of 350 gf/cm or more. The adhesion strength may be 350 gf/cm or more, 400 gf/cm or more, 450 gf/cm or more, or 500 gf/cm or more. The adhesion strength may be 1300 gf/cm or less. In such cases, excellent adhesion can be maintained over a long term even during operation of the packaging substrate.

A solder resist layer (not shown) may be further disposed on the second surface insulating layer 94.

The foregoing configurations on the second surface insulating layer 94 are collectively referred to as a lower layer 800.

When an electrically conductive layer and the like are further disposed on the first surface insulating layer 92 and/or the second surface insulating layer 94, the structure can be utilized as a packaging substrate 1.

An electronic element may be disposed on the packaging substrate 1 (see FIG. 7).

Detailed descriptions of the configurations and materials of each layer are omitted to avoid redundancy with the foregoing description.

Hereinafter, embodiments of the invention will be described in more detail with specific examples. The following examples are merely illustrative to aid understanding of the embodiments of the invention, and the scope of the invention is not limited thereto.

### Example 1

A glass substrate in which through-holes and a cavity are disposed and in which an electrically conductive layer is disposed in the through-holes is prepared. The glass substrate is placed on a PI tape (adhesive material thickness: 25 μm), and a cavity element is disposed to fix their positions. Thereafter, a dispensing process is carried out: an epoxy resin is injected at a temperature of about 80° C. and cured. Subsequently, an adhesion-strengthening treatment is performed. The treatment is carried out by applying Novabond, and Novabond performs adhesion strengthening by an oxidation method.

An ABF layer is disposed on the Novabond-treated glass substrate, followed by vacuum lamination and curing. Thereafter, the PI tape is removed. At this time, adhesive residues were substantially not left, or they could be easily removed by a cleaning process. The cleaning process is carried out by plasma desmear treatment, using a gas prepared by mixing O2 and CF4 at a volume ratio of 8:2, operated at 3000 W for 4 minutes.

Novabond treatment is additionally performed on the lower surface side of the glass substrate on which the ABF layer is not disposed, and thereafter an ABF layer is disposed on the lower surface, followed by vacuum lamination and curing. The curing conditions are 150° C. for 60 minutes.

Two evaluation items are confirmed as results. First, after removal of the adhesive layer, how much adhesive residue remains on the exposed surface is checked. This is evaluated by visual inspection, and in Example 1 no residue is visually observed.

Next, the bonding force between the core electrically conductive layer located on the lower side of the glass substrate and the ABF is tested. The test is performed as a peel test, and the bonding force is confirmed to be about 800 gf/cm.

### Example 2

All other conditions are carried out in the same manner, except that the adhesion-strengthening treatment is performed by a wet-etching method instead of Novabond. The wet etching is conducted using CZ-8101.

In Example 2, no residue is visually observed. The bonding force is confirmed to be about 500 gf/cm.

### Example 3

All other conditions are carried out in the same manner, except that the adhesion-strengthening treatment uses a silane coupling agent instead of Novabond. As the silane coupling a gent, 3-methacryloxypropyl trimethoxysilane is applied.

In Example 3, no residue is visually observed. The bonding force is confirmed to be about 400 gf/cm.

### Comparative Example 1

A glass substrate is prepared in which through-holes and a cavity are disposed and in which an electrically conductive layer is disposed in the through-holes. An adhesion-strengthening treatment is then performed thereon. The treatment is carried out by applying Novabond, which performs adhesion strengthening by an oxidation method.

The glass substrate is placed on a PI tape (adhesive material thickness: 25 μm), and a cavity element is disposed to fix their positions.

An ABF layer is disposed on the glass substrate, followed by vacuum lamination and curing. Thereafter, removal of the PI tape is attempted. Upon removal of the PI tape, a substantial amount of adhesive residue remains. Subsequently, Novabond treatment is additionally performed on the lower surface side of the glass substrate on which the ABF layer is not disposed, and then an ABF layer is disposed on the lower surface, followed by vacuum lamination and curing. The curing conditions are 150° C. for 60 minutes. However, the adhesion test between the core electrically conductive layer located on the lower side of the glass substrate and the ABF is difficult to perform.

### Comparative Example 2

Manufacturing is carried out in the same manner as in Comparative Example 1, except that a cleaning process is applied after removal of the PI tape. The cleaning process is conducted under the same conditions as in Example 1.

After removal of the adhesive layer and execution of the cleaning process, how much adhesive residue remains on the exposed surface is checked. This is evaluated by visual inspection, and in Comparative Example 2, residue is visually observed on about 70% of the area.

Next, the bonding force between the core electrically conductive layer located on the lower side of the glass substrate and the ABF is tested. The test is performed as a peel test, and the bonding force is confirmed to be about 150 gf/cm.

### Comparative Example 3

Manufacturing is carried out in the same manner as in Comparative Example 2, except that the wet-etching method applied in Example 2 is used.

After removal of the adhesive layer and execution of the cleaning process, how much adhesive residue remains on the exposed surface is checked. This is evaluated by visual inspection, and in Comparative Example 3, residue is visually observed on about 30% of the area.

Next, the bonding force between the core electrically conductive layer located on the lower side of the glass substrate and the ABF is tested. The test is performed as a peel test, and the bonding force is confirmed to be about 250 gf/cm.

According to the embodiments, the method for manufacturing the core substrate and the core substrate included in a packaging substrate may manufacture a core substrate having excellent interfacial adhesion by a more simplified method.

Although preferred embodiments of the present invention have been described in detail above, the scope of the present invention is not limited thereto, and various modifications and improvements made by those skilled in the art using the basic concept of the present invention defined in the following claims also fall within the scope of the present invention.

What is claimed is:

1. A method for manufacturing a core substrate included in a packaging substrate, the method comprising:
operation A of preparing a glass core in which through-holes and a cavity are disposed;
operation B of preparing an adhesive laminate in which an adhesive layer is disposed on a lower surface of the glass core such that the glass core and the adhesive layer are vertically arranged;
operation C of disposing a cavity element in the cavity of the adhesive laminate;
operation D of preparing a fill-in laminate by disposing a dispensing material in a space between the cavity element and a wall surface of the cavity;
operation E of preparing an adhesion-strengthening treatment layer by performing an adhesion-strengthening treatment on a surface of the fill-in laminate;
operation F of preparing an insulating laminate by forming a first surface insulating layer on an upper surface of the glass core of the fill-in laminate; and
operation G of preparing the core substrate by removing the adhesive layer from the insulating laminate and forming a second surface insulating layer on the lower surface of the glass core;
wherein a core electrically conductive layer, which is an electrically conductive layer, is disposed on at least a portion of a surface of the glass core.

2. The method of claim 1,
wherein a process including an adhesion-strengthening treatment is substantially not applied between the operation A and the operation B.

3. The method of claim 1,
wherein, in the operation B, the adhesive layer is constituted by an adhesive material disposed on a support film, and a thickness of the adhesive material is 10 μm or more.

4. The method of claim 1,
wherein, in the operation E, the adhesion-strengthening treatment comprises processing the surface such that a surface roughness Ry of the core electrically conductive layer is within a range of 20 nm to 200 nm.

5. The method of claim 1,
wherein, in the operation E, the adhesion-strengthening treatment comprises performing a bonding-strength enhancing compound treatment on a surface of the glass core.

6. The method of claim 1, further comprising
a wiring operation of forming electrical conductivity after the operation F, wherein, in the wiring operation, an electrically conductive layer on the first surface insulating layer has an adhesion strength on the glass core of 350 gf/cm or more.

7. The method of claim 1,
wherein, in the operation G, substantially no residue of the adhesive layer remains on the core electrically conductive layer on the lower surface of the glass core from which the adhesive layer has been removed.

8. The method of claim 1,
wherein the operation G further comprises, after removal of the adhesive layer, a process of adding an adhesion-strengthening treatment layer to the insulating laminate by performing an adhesion-strengthening treatment, and,
after the process of adding the adhesion-strengthening treatment layer, is an operation of forming the second surface insulating layer on the lower surface of the glass core.

9. A core substrate included in a packaging substrate, comprising:
a glass core in which through-holes and a cavity are disposed;
a cavity element that is an element disposed in the cavity;
a first surface insulating layer that is an insulating layer disposed on an upper surface of the glass core; and
a second surface insulating layer that is an insulating layer disposed on a lower surface of the glass core;
wherein a core electrically conductive layer, which is an electrically conductive layer, is disposed on at least a portion of a surface of the glass core;
a dispensing material is disposed in a space between the cavity element and a wall surface of the cavity;
an electrically conductive layer is further disposed on the second surface insulating layer; and
the electrically conductive layer on the second surface insulating layer has an adhesion strength on the glass core of 350 gf/cm or more.

10. The core substrate of claim 9,
wherein substantially no residue of an adhesive layer remains on the core electrically conductive layer on a side where an adhesion-strengthening treatment layer is not disposed.

11. The core substrate of claim 9,
wherein, for the core electrically conductive layer disposed in the through-hole, a thickness of the adhesion-strengthening treatment layer on one of the first surface insulating layer side and the second surface insulating layer side is thicker.

12. The core substrate of claim 9,
wherein, for the core electrically conductive layer disposed in the through-hole, the adhesion-strengthening treatment layer is disposed only on one of the first surface insulating layer side and the second surface insulating layer side.
